(19) United States
(12) Patent Application Publication
(10) Pub. No.: US 2010/0237359 A1
(43) Pub. Date: Sep. 23, 2010

(54) FLAT AND THIN LED-BASED LUMINARY PROVIDING COLLIMATED LIGHT

(75) Inventors: Hugo J. Cornelissen, Eindhoven (NL); Willem L. Ijzerman, Eindhoven (NL); Michel C. J. M. Vissenberg, Eindhoven (NL)

Correspondence Address: Philips Intellectual Property and Standards, P.O. Box 3001, Briarcliff Manor, NY, 10510-8001, US

(73) Assignee: KONINKLIJKE PHILIPS ELECTRONICS N V, Eindhoven (NL)

(21) Appl. No.: 12/377,564

(22) PCT Filed: Sep. 12, 2007
(86) PCT No.: PCT/IB07/53681

§ 371 Date: Feb. 13, 2009

(30) Foreign Application Priority Data
Sep. 15, 2006 (EP) 06120717.1

(51) Int. Cl. H01L 27/15

(52) U.S. Cl. 257/88; 257/E27.12

(57) ABSTRACT

A light-emitting device (100), comprising a plurality of light emitting diodes (107) arranged spaced apart from each other on a substrate (108), is provided. The device further comprises a light guide plate (101) having a front surface (102) and an opposing back surface (103) that is provided with an array of protrusions (104) extending towards said substrate. The light guide plate is arranged such that light-emitting diodes emits light towards light receiving faces (105) of the protrusions (104). Further, collimators (110) are arranged between the light emitting diodes and the light receiving faces, to collimate the light before it enters the light guide plate.

The light from the plurality of LEDs will be transmitted in to the light guide plate and will be distributed therein before exiting the light guide plate via the front side thereof. Thus, the present invention provides a light-emitting device that provides well-distributed and collimated light from a plurality of point light sources.

### FIELD OF THE INVENTION

The present invention relates to a light-emitting device comprising a plurality of mutually spaced apart light emitting diodes arranged on a substrate, and a light guide plate.

### BACKGROUND OF THE INVENTION

Especially if applied in, for instance an office or a professional environment, luminaries should fulfill several requirements. Firstly, the light source should have a sufficiently long lifetime. Conventional luminaries are often based on fluorescent tubes, which have a relatively limited lifetime. In a typical office environment, the tubes themselves needs to be replaced every 6000 hours. This corresponds to a replacement every 2 years, which adds to the cost of ownership.

Secondly, the light output of the luminary should be robust against dust and other dirt. A luminary that collects dust will become less efficient, since the dirt blocks light. Since cleaning the luminary is an expensive matter, the design should be robust against dust and dirt.

Thirdly, the luminary should satisfy an anti-glare requirement, (the unified glare ratio should be sufficiently small). This anti-glare requirement means that the luminary should not show any bright spots. In particular, there should be no bright spots if the luminary is viewed under an oblique angle. A luminary of the prior art is disclosed in U.S. Pat. No. 6,241,358, describing a lighting panel consisting of a set of light guide blocks in tandem arrangement, where a separate fluorescent tube provide light for each light guide block. The light from the fluorescent tubes is transmitted into the respective light guide block, is distributed therein and is transmitted through an output surface of the light guide block.

However, as mentioned above, fluorescent tubes have a limited lifetime and are expensive to replace. Further, the breakdown of a single fluorescent tube in this prior art luminary has a drastic negative impact on the lighting capacity of the lighting panel and on the homogeneity of the light from the lighting panel. Thus, when one of the tubes breaks down, it will be necessary to replace this broken tube immediately.

Further, fluorescent tubes emit a constant spectrum, which limits the color variability capacity of such a lighting panel.

### SUMMARY OF THE INVENTION

It is an object of the present invention to at least partly overcome the problems of the prior art and to provide a flat panel lighting device that has a long lifetime.

A further object of the present invention is to provide a light-emitting device that provides light that is well collimated.

The present inventors have found that the above objects may be achieved by means of a light-emitting device accorded to the appended claims. Thus, in one aspect, the present invention provides a light emitting device, comprising a plurality of light emitting diodes arranged mutually spaced apart on a substrate, said light emitting diodes being arranged to emit light in a general direction along the surface of said substrate.

Further, the light emitting device comprises a light guide plate of a translucent material having a back surface facing said substrate and an opposing front surface, said back surface comprising a first array of protrusions extending towards said substrate, said protrusions providing a light receiving face arranged to transmit light from light emitting diodes into said light guide plate and a light reflection face arranged to reflect light in said light guide plate, having a directional component along said general direction of light, towards said front side.

Yet further, collimators are arranged in the light path between said light emitting diodes and said light receiving faces. The collimators are typically funnel-shaped.

The light from the plurality of LEDs will be transmitted in to the light guide plate and will be distributed therein before exiting the light guide plate via the front side thereof. Thus, the present invention provides a light-emitting device that provides well-distributed light from a plurality of point light sources.

The use of light emitting diodes as primary light sources is advantageous as they have a long lifetime. Hence, service intervals will be extended, leading to a lower cost of ownership.

Further, light emitting diodes are capable of emitting light of saturated colors, allowing the light-emitting device to produce light with high color-variability. In preferred embodiments of the invention, the collimators collimate the light emitted by said light emitting diodes in a direction along the surface of said substrate and perpendicular to the general direction of light emitted by the light emitting diodes.

Due to its design, the light guide plate will act as a collimator such that light exiting the light guide plate will be collimated in the direction along the first array of protrusions. However, the light guide plate will essentially not provide any collimation of light in the direction perpendicular to the direction along the first array or protrusions. By arranging collimators such that the light entering the light guide plate is collimated in the direction, along the surface of said substrate and perpendicular to the general direction of light emitted by the light emitting diodes, the light exiting the light guide plate will be collimated in the direction perpendicular to the direction along the first array or protrusions.

In embodiments of the present invention, a reflective layer may be arranged between collimators and the light guide plate, such that light exiting the light guide plate via the back surface can be reflected back towards the front surface of the light guide plate, thus increasing the light utilization efficiency of the device.

Further, another reflective layer may be arranged between collimators and the substrate in order to prevent light from exiting the collimator towards the substrate, and to prevent that scattered light from light emitting diodes enters the collimator through a surface thereof not intended for receiving light. In embodiments of the present invention, reflective layers may be arranged at the back surface side of the reflection face of said protrusions of the first array.

Such reflective layer increases the light utilization efficiency, since light exiting the light guide plate via the reflection faces can be reflected back towards the front surface. Further, it prevents light to be transmitted into the light guide plate via the reflection faces. In embodiments of the present invention, more than one light emitting diode may provide light to a single light receiving face of a protrusion.

For example, a plurality of LEDs arranged to provide light to a single light receiving face may together form an extended light source, that will not fully be dysfunctional in the case one or a few of the LEDS in that plurality of LEDs break down, since the neighboring LEDs will still be in operation.

Further, a plurality of LEDs of different colors, typically independently addressable, may provide light to a single receiving face in order to provide a color variable light-emitting device. Typically, the protrusions of said first array have triangularly shaped cross-section, preferably wherein the angle between the light receiving face and the front surface of the light guide plate is larger than the angle between the light reflecting face and the front surface. In embodiments of the present invention, the substrate on which the light emitting diodes are arranged may comprises a plurality of mutually spaced apart recesses.

Such recesses may be used to improve and facilitate the alignment of the light guide plate on the substrate. In embodiments of the present invention, a redirection sheet may be arranged at the front side of said light guide plate, where the redirection sheet has a prism-faced surface facing the front side of the light guide plate.

Such a redirection sheet may be arranged in order to redirect the light exiting the light guide plate into a desired direction.

### BRIEF DESCRIPTION OF THE DRAWINGS

This and other aspects of the present invention will now be described in more detail, with reference to the appended drawings showing currently preferred embodiments of the invention.

FIG. 1a illustrates, in cross-sectional view, an embodiment of a light-emitting device of the present invention.

FIG. 1b illustrates, in perspective view, the embodiment of FIG. 1a.

FIG. 1c illustrates an alternative design of the collimator shown in FIG. 1b.

FIG. 2 illustrates another embodiment of a light-emitting device of the present invention.

FIG. 3 illustrates yet another embodiment of a light emitting device of the present invention.

### DETAILED DESCRIPTION OF PREFERRED EMBODIMENTS

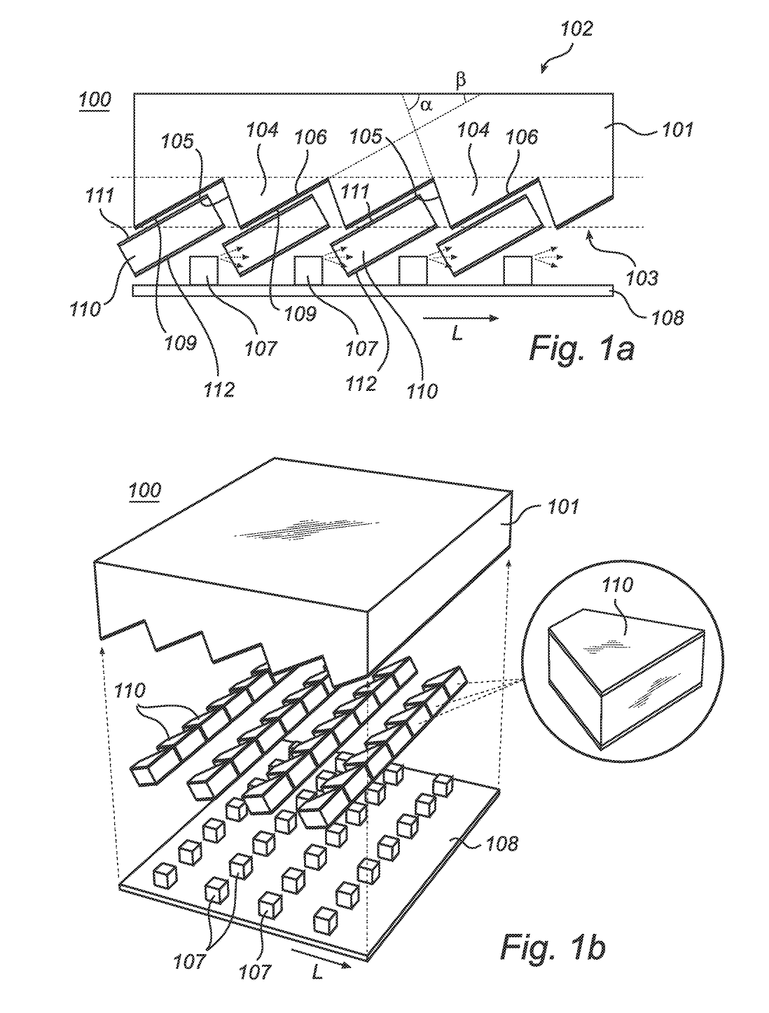

A light emitting device 100 of one embodiment of the present invention is illustrated in FIG. 1a, and comprises an array of a plurality of light emitting diodes (LEDs) 107, arranged mutually spaced apart on a substrate 108.

The light emitting diodes 107 are arranged to emit light in essentially the same general direction L, essentially along the surface of the substrate 108, and in the direction of the array of the LEDs.

LEDs capable of emitting light in a general direction essentially along the surface of the substrate that they are mounted on are especially suitable for use in the present invention. Examples of such diodes are those commonly known as side emitting diodes. The term “light emitting diode”, herein abbreviated “LED” refers however to any type of light emitting diode known to those skilled in the art, and encompasses, but is not limited to, inorganic based LEDs, organic based LEDs (OLEDs and polyLEDs) and laser diodes.

The light-emitting device 100 further comprises a light guide plate 101 of a translucent material having a front surface 102 and an opposing back surface 103 facing the light emitting diodes 107. The light guide plate is arranged to receive light from the light emitting diodes via the back surface 103, to distribute the received light and to transmit the distributed light to the surroundings via the front surface 102.

Suitable materials for use in the light guide plate 101 include translucent materials such as, but not limited to, polymeric materials, i.e. PMMA or polycarbonate, ceramic materials and glass materials.

The back surface 103 of the light guide plate 101 presents a first array of protrusions 104 extending towards the substrate 108. The protrusions 104 are designed to have a light receiving face 105, through which face light from the light emitting diodes 107 enters into the light guide plate 101. The protrusions 104 also has a light reflection face 106, typically the alternate face of the protrusion, on which face light, that has been transmitted into the light guide 101, is reflected towards the front surface of the light guide plate.

The light guide plate 101 is arranged such that the first array of protrusions 104 is aligned to the array of LEDs 107 on the substrate 108.

Typically, the protrusions have a triangularly shaped cross-section, preferably as illustrated in FIG. 1a, being asymmetric such that the receiving face 105 has a steeper slope than the reflection face 106.

Typically, the angle α between the receiving face 105 and the front surface 102 of the light guide plate 101 is larger than the angle β between the reflection face 106 and the front surface 102.

The angle α is typically in the range of from 60 to 90°, and the angle β is typically in the range of from 1 to 15°.

The pitch of the protrusions 104 of the light guide plate 101, i.e. the repetitive distance between adjacent protrusions, is typically in the range of from 1 to 30 mm, for example from about 10 to about 20 mm.

In operation, light from the light emitting diodes 107 is transmitted into the light guide plate via the receiving faces 105 of the protrusions 104. When traveling in the light guide plate, the light will alternately encounter the front surface 102 of the light guide plate or a reflection face 106 of a protrusion.

Depending on the angle of incidence upon encountering the front surface 102, and according to Snell's law of refraction, the light is transmitted out of the light guide plate 101, or is reflected back (total internal reflection) into the light guide plate, towards the back surface 103 where it will encounter a reflection face 106 for reflection again towards the front surface 102. Due to the angle between the front surface 102 and the reflection face 106, the incidence angle at this following encounter with the front surface 102 will be lower than the incidence angle at the preceding encounter, until the incidence angle eventually becomes lower than the critical angle for transmission out of the light guide.

The reflection on the reflection faces 106 does at least partly depend on total internal reflection on theses surfaces.

However, light will also be able to exit the light guide through the back surface 103 of the light guide plate, when the angle of incidence on the reflection faces 106 so allows. In able to utilize also light being transmitted out of the light guide plate at the back surface, it may be advantageous to provide the substrate 108 on which the light emitting diodes 107 are arranged, with a reflective coating or the like in order to reflect this light back towards and into the light guide plate 101.

In addition, the reflection faces 106 may be provided with a reflective coating 109. Light transmitted out of the light guide plate via the reflection faces 106 will be reflected back towards the front surface of the light guide plate. This will enhance the light utilization efficiency of the device.

Such reflective layer 109 may for example consist of a foil made of a reflecting material, and may be arranged between the reflection face 106 and the substrate 108, or between the reflection face 106 and a collimator 110, typically near the reflection face 106, or as a reflective coating on the back surface side of the reflection surface 106. Preferably, the reflective layer 109 consists of a reflective foil positioned against the reflection face 106. In the present embodiment, collimators 110 are located in the light path between the light emitting diodes 107 and the corresponding receiving faces 105 to collimate the light before it enters the light guide plate 101.

Especially, the collimators 110 are adapted to collimate the light in the direction along the surface of the substrate 108 and perpendicular to the general direction of light emitted by the light emitting diodes.

As used herein, the term “collimate” refer to the action of reducing the angular spread of light. Consequently, “collimator” refers to an optical element capable of receiving light from a light source and reducing the angular spread of the received light.

Typically, the collimators 110 have the shape of a tapered funnel, so that the collimators have a gradually increasing cross-sectional area, with the smallest area at the side of the collimator receiving the light from the LED, the input side, and largest area, the output side, for transmitting the light out of the collimator and into the light receiving face 105 of the protrusion 104.

Due to reflection of light on the tapered sidewalls of the collimator, the light exiting the collimator via the output side will have a smaller angular spread (i.e. will be more collimated) than the light entering the collimator at the output side, as is well known to those skilled in the art.

As is illustrated in FIG. 1b, the collimator 110 may have straight tapering sidewalls, but as illustrated in FIG. 1c, the collimator 110 may also have curved tapering sidewalls. A specific example of a collimator 110 having curved tapering sidewalls is commonly known as a compound parabolic concentrator (CPC) collimator, where the curvature of the sidewalls resembles the curvature of a parabola.

One advantage of using a collimator having curved tapering sidewalls is that the length of such a collimator may be reduced in comparison with a collimator having straight tapering sidewalls in order to achieve a specific collimation. Hence a more compact collimator may be obtained. However, also other shapes of the collimator known to those skilled in the art may be used in the present invention to collimate the light before it enters the light guide plate.

For example, the collimators may be designed to also collimate the light in a direction along the normal of the substrate in order to provide light being well collimated in both directions orthogonal to the main direction of light (L).

The sidewalls of the collimators 110 may be clear walls, where the reflection of light within the collimators relies on total internal reflection. However, at least some of the sidewalls (except for the input and output surfaces) may be non-transparent mirroring surfaces.

A reflective layer 111 may optionally be arranged between the collimator 110 and the light guide plate, in order to prevent light from exiting the collimator towards the light guide plate elsewhere than through the intended output side of the collimator.

Further, a reflective layer 112 may optionally be arranged between the collimator 110 and the substrate in order to prevent light from exiting the collimator towards the substrate.

The reflective layers 111 and 112 are typically reflective foils positioned against the respective surfaces of the collimator 110, or may alternatively be reflective coatings on the collimator.

The reflective layer 111 may be may be a separate layer from, or may alternatively in fact be the reflective layer 109 descried above, such as a two-sided mirror.

As is shown in FIG. 1b, the array of protrusions 104 is an array of extended, mutually parallel protrusions, and where an array of more than one light emitting diode is arranged provide light to a single receiving face 105.

The collimators 110 collimating the light from such an array of light emitting diodes may be separate collimators for each of the LEDs in the array, or may be an arrangement of several collimators joined together side by side to receive and collimate the light from several LEDs.

As is shown in FIG. 1b, the array of mutually spaced apart LEDs 107 may be an array of mutually spaced apart rows, where each row comprises multiple LEDs. The array of protrusions 104 may be an array of extended, mutually parallel protrusions, where a whole row, i.e. more than one light emitting diode, is located in a single space between two adjacent protrusions. Thus, more than one light emitting diode 107 provides light to the receiving face 105.

For example, the multiple LEDs 107 forming a row and providing light to a single receiving face 105 may act as a spatially extended, linear, light source. If one of these light emitting diodes in such a row incidentally break down, the impact on the overall performance of the light emitting device is only minor, since the neighboring light emitting diodes providing light to the same receiving face as the broken light emitting diode still are functioning.

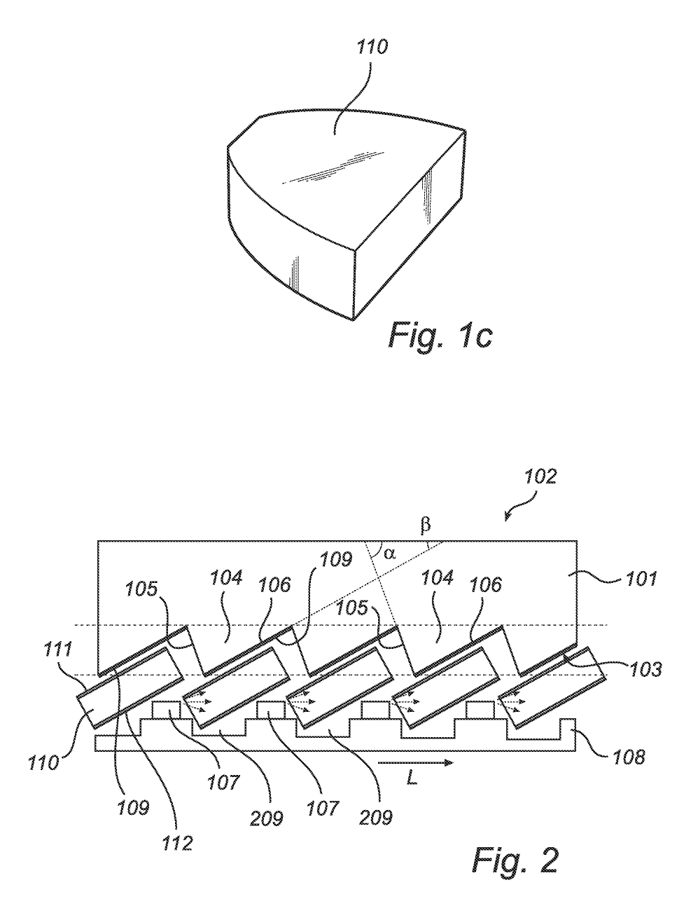

Further, light-emitting diodes of more than one color may be used to provide light to the same receiving face, in order to provide a color variable light-emitting device. For example, three or more independently addressable light emitting diodes of different colors, for example a red, a green and a blue LED, may form a color variable lighting unit (an RGB-unit). In another embodiment of the present invention, as is illustrated in FIG. 2, the substrate 108 on which the LEDs are arranged, comprises a plurality of recesses 209 between mutually spaced apart light emitting diodes 107. The plurality of recesses 209 in the substrate 108 is preferably aligned to the periodic nature of the light guide plate, i.e. to the array of protrusions 104. Hence, the distance between two adjacent such recesses 209 corresponds to the distance between two adjacent protrusions 104 of the light guide plate 101.

For example, portions of the collimators 110 may be located in the recesses 209. This improves and facilitates the alignment of the LEDs 107 with the receiving faces 105 of the protrusions 104 of the light guide plate. As will be apparent to those skilled in the art, the light from a light-emitting device as illustrated in FIGS. 1 and 2 will typically exit the light guide plate via the front surface 102 thereof into the surroundings at an noticeable angle with respect to the normal of the front surface 102.

For instance, such a light-emitting device may be well suited for illuminating the ceiling when hung on a wall, or for illuminating a wall when arranged in the ceiling, but also for other purposes where light emission out of the normal of the front surface is desired.

However, in certain applications, it is desired to redirect the light exiting the light guide plate, for example to obtain light having a main direction at or close to the normal of the front surface of the light guide plate.

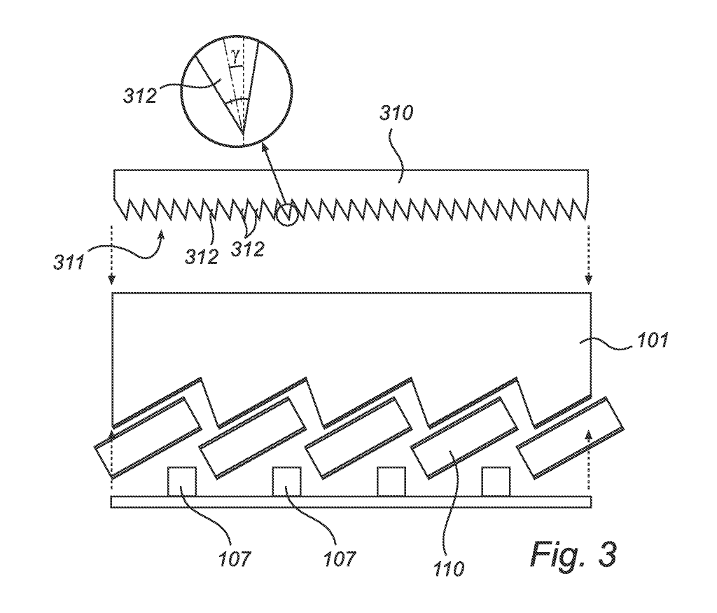

Thus, in embodiments of the present invention, as illustrated in FIG. 3, a redirection sheet 310 may be arranged at the front surface 102 to receive light that exits the light guide plate 101 via the front surface 102, in order to redirect the main direction of this light.

An example of such a redirection sheet 310 comprises a sheet of a translucent material (i.e. plastic, ceramic or glass), which has a prismatic surface 311 facing the front surface 102 of the light guide plate.

In an embodiment, the prismatic surface 311 comprises a second array of mutually parallel protrusions 312. For high efficiency, the protrusions 312 of the second array are advantageously essentially parallel to the protrusions 104 of the light guide plate 101.

Typically, the protrusions 312 of the second array have a triangularly shaped cross-section with an apex angle in the range of from 20 to 70°. The protrusions 312 of the second array are typically formed at a pitch (distance between two adjacent protrusions) that are markedly lower than the pitch of the protrusions 104 of the first array. Typically, the pitch of the protrusions 312 of the second array is in the range of about 50 to 500 μm.

The protrusions 312 of the second array may be symmetric or asymmetric with respect to the normal of the front surface 102 of the light guide plate, in the sense that the center line of the protrusions may be parallel (symmetric) or non-parallel (asymmetric) to the normal of the front surface 102.

The centerline of a protrusion having a triangularly shaped cross-section is a thought line that divides the apex angle into to two equally large portions.

One way of quantifying the symmetry/asymmetry is to define a tilt angle γ as the angle between the centerline of a protrusion 312 and the normal to the front surface 102 of the light guide plate 101. Hence, γ=0° refers to a symmetric protrusion, γ>0° refers to an asymmetric protrusion tilted along the general direction of light emitted by the light emitting diodes, and γ<0° refers to an asymmetric protrusion tilted against the general direction of light emitted by the light emitting diodes. Hence, if the general direction of light emitted by the light emitting diodes is to the right, γ>0° refers to a protrusion tilted to the right, and γ<0° refers to a protrusion tilted to the left (as shown in FIG. 3).

The tilt angle γ of the protrusions 312 of the second array is typically in the range of from −15° to 15°, and may be constant or may vary along the array.

The apex and tilt angle of the protrusions 312 of the second array have been shown to affect the light exiting the redirection sheet into the surrounding.

One effect of a redirection sheet 310 is that the exiting light is given a tendency to show a plurality of intensity peaks at different angles relative to the normal of the redirection sheet.

At an apex angle value of about 40°, only one intensity peak appeared. Thus, in some embodiments of the present invention, about 40° represents a preferred apex angle, since a single intensity peak is achieved.

Further, at tilt angle γ of about 11°, the light exits the redirection sheet 310 approximately parallel to the normal of the redirection sheet. Thus, in some embodiments of the present invention, a tilt angle γ of about 11° is preferred since such a light-emitting device produces light perpendicular to the surface of the light-emitting device. At a lower tilt angle, for example 0°, light exits the redirection sheet 310 at a negative angle to the normal of the redirection sheet. At a higher tilt, such as 15°, light exits the redirection sheet 310 at a positive angle to the normal of the redirection sheet. In yet an embodiment of the present invention, the tilt angle γ of the protrusions 312 of the second array varies along the extension of the second array in order to direct light from different portions of the device into different directions. For example, the tilt angle γ may decrease, for example from about 15° to −5°, such as from 11° to 0°, along the second array in the general direction of light emitted by the LEDs (i.e. if the LEDs are arranged to emit light generally to the right, the tilt angle γ of the protrusions 312 of the second array is higher in a left portion of the second array then in a right portion of the array). This manner of varying the tilt angle will lead to a focusing of the light from the light-emitting device of the present invention.

The person skilled in the art realizes that the present invention by no means is limited to the preferred embodiments described above. On the contrary, many modifications and variations are possible within the scope of the appended claims. For example, the redirection sheet 310 may be divided into two or more domains, where the tilt angle γ of the protrusions 312 of the redirection sheet has a first value in a first such domain, and a second such value in a second domain. This may be used in order to achieve a light distribution with for example two intensity peaks at two different angles.

1. Light emitting device, comprising:
a plurality of light emitting diodes, spaced apart from each other on a substrate, said light emitting diodes being arranged to emit light in a general direction (L) along the surface of said substrate,
a light guide plate comprising a translucent material and having a back surface facing said substrate and an opposing front surface, said back surface comprising a first array of protrusions extending towards said substrate, said protrusions forming a light receiving face for transmitting light from the light emitting diodes into said light guide plate and a light reflection face for reflecting light in said light guide plate, and
a plurality of collimators arranged in the light path between said light emitting diodes and said first array of protrusions.

2. A light emitting device according to claim 1, wherein said collimators collimate the light emitted by said light emitting diodes in a direction along the surface of said substrate and perpendicular to the general direction (L) of light emitted by said light emitting diodes.

3. A light emitting device according to claim 1, wherein said collimators are funnel-shaped.

4. A light emitting device according to claim 1, wherein a reflecting surface is arranged between said light guide plate and said plurality of collimators.

5. A light emitting device according to claim 1, wherein a reflective surface is arranged between said substrate and said plurality of collimators.

6-7. (canceled)

8. A light emitting device according to claim 1, wherein said first array of protrusions comprises extended protrusions arranged substantially in parallel relative to each other.

9. A light emitting device according to claim 1, wherein said protrusions of said first array have triangularly shaped cross-section.

10. A light emitting device according to claim 1, wherein the angle (α) between said light receiving face and said front surface is larger than the angle (β) between said light reflecting face and said front surface.

11. A light emitting device according to claim 1, wherein said substrate defines a plurality of spaced apart recesses.

12. A light emitting device according to claim 1, wherein a redirection sheet is arranged at said front side of said light guide plate, said redirection sheet having a prism-faced surface facing said front side.
